(19) United States
(12) Patent Application Publication
(10) Pub. No.: US 2011/0237001 A1
(43) Pub. Date: Sep. 29, 2011

(54) SEMICONDUCTOR CHIP USED FOR EVALUATION, EVALUATION SYSTEM, AND REPAIRING METHOD THEREOF

(76) Inventors: Takehiko HASEBE, Mobara (JP); Masako Kato, Yokohama (JP); Yoshihide Yamaguchi, Yokohama (JP); Masashi Nishiki, Yokohama (JP); Naoki Matsushima, Chiba (JP); Teiichi Inada, Tsukuba (JP); Rei Yamamoto, Tsukuba (JP); Hiroyuki Temmei, Odawara (JP); Ukyo Ikeda, Fujisawa (JP)

(21) Appl. No.: 13/034,510

(22) Filed: Feb. 24, 2011

(30) Foreign Application Priority Data
Feb. 25, 2010 (JP) 2010-040199
Jan. 17, 2011 (JP) 2011-006948

(51) Int. Cl. H01L 21/02; H01L 23/544; G01K 7/16

(52) U.S. Cl. 438/4; 257/48; 374/185; 257/E21.002; 257/E23.179; 374/E07.018

(57) ABSTRACT

A technique for evaluating a semiconductor chip is provided. The semiconductor chip is mounted on a mount substrate, the semiconductor chip laminating on one surface of a silicone substrate, at least any of a metal wiring film 101 serving as a resistance temperature detector made up of multiple regions and a metal wiring film 102 serving as a heater made up of one or more regions, and an electrode 103 for connecting the metal wiring film 101 and the metal wiring film 102 with the mount substrate. Then, the metal wiring film 101 is electrically connected with an ammeter and a voltmeter, and the metal wiring film 102 is electrically connected with a power source, thereby providing an evaluation system which is capable of evaluating temperature measurement, heating, and temperature profile in each of the regions on the semiconductor chip.

### INCORPORATION BY REFERENCE

This application claims priority based on a Japanese patent application, No. 2010-040199 filed on Feb. 25, 2010 and a Japanese patent application, No. 2011-006948 filed on Jan. 17, 2011, the entire contents of which are incorporated herein by reference.

### BACKGROUND OF THE INVENTION

1. Field of the Invention

The present invention relates to an evaluation technique of semiconductor equipment.

2. Description of the Related Art

A semiconductor chip, such as a large scale integrated circuit (LSI) and memory, strongly requires speeding up of signal processing and enhancement of mounting density. Therefore, fine designing of a semiconductor device including field effect transistor (FET) has been developed. Also for a substrate for mounting a semiconductor chip thereon, there has been developed a technique to achieve higher density of wiring, represented by a method such as a build-up method.

Furthermore, due to ease of formulation as a system, a semiconductor package that combines multiple semiconductor chips is getting actively developed, and particularly, a three-dimensional mounting technique is attracting attention, the technique laminating thinly polished semiconductor chips. In this kind of three-dimensional mounting structure, wiring density on both the semiconductor chip and the substrate is enhanced, and further, fine design and multiple-pin design rapidly progress in terminals which electrically connect the semiconductor chip with the substrate.

As for the high-density semiconductor chip as described above, there are enormous number of materials to be used for mounting such a semiconductor chip, and it is manufactured after going through complicated processes. Generally for laminating the semiconductor chip, heating has to be repeated every time when lamination is performed, and so-called temperature stratification process is employed, which performs the heating processes in downstream steps using a temperature lower than a temperature used in upstream steps, so that reliability of the processes in the upstream steps may not become impaired. Therefore, it is essential to accurately figure out a temperature history in each process, in order to develop materials or establish a manufacturing process.

In addition, evaluations of mounting reliability as to a manufactured semiconductor are generally carried out in conformity with the “Environmental and endurance test methods for semiconductor devices” described in the JEITA technical standard EIAJ ED4701/100. The evaluation of mounting reliability is conducted by evaluating temperature changes due to thermal resistance. The thermal resistance may be caused by current flowing in a junction of the semiconductor chip being a heat source, the junction corresponding to finely designed wiring, such as tungsten, aluminum, and copper constituting the semiconductor device, or the thermal resistance may be caused by electron transfer between FET (field-effect transistor) electrodes (between Source and Drain).

For measuring the temperature history as described above, conventionally, there has been employed a method for mounting a thermocouple as a thermo sensor, on the semiconductor chip or around the semiconductor package.

By way of example, the non patent document “Hitachi Review Vol. 91, No. 05, p. 456” suggests a solution by a device used for evaluation, which is directed to analysis of stress and/or heat evolution, being issues of concern in high-density mounting.

However, in the method which mounts the thermocouple serving as the thermo sensor, it is difficult to set the thermocouple on the junction which is an actual evaluation target (heat source). Therefore, in order to carry out temperature measurement, the thermocouple has been provided on a backside of a semiconductor chip or a semiconductor package, or on the substrate around them, at a place distant from the junction. With this configuration, it is possible neither to figure out accurate temperature of the semiconductor chip being the heat source, nor to produce an increase in temperature during the evaluation test.

The present invention has been made to solve the problem above and an object of the invention is to provide a technique for evaluating the semiconductor chip.

### SUMMARY OF THE INVENTION

In order to solve the problem above, an evaluation system according to the present invention employs the configuration as defined by the scope of the appended claims.

The present application includes more than one means to solve the problem above, and as one of the examples, it is directed to an evaluation system for evaluating a semiconductor chip, the system having on one surface of a silicon substrate, the semiconductor chip on which at least one of first wiring film and second wiring film, and an electrode electrically connecting the first wiring film and the second wiring film, are laminated, the first wiring film serving as a resistance temperature detector made up of multiple regions and the second wiring film serving as a heater made up of one or more regions, a mount substrate for mounting the semiconductor chip thereon, and on the other surface of the silicon substrate, a thermally conductive material being fixed on the mount substrate, wherein, the first wiring film is electrically connected to an ammeter and a voltmeter, and the second wiring film is electrically connected to a power source.

According to the present invention, a technique for evaluating semiconductor equipment is provided.

### BRIEF DESCRIPTION OF THE DRAWINGS

FIG. 1 is a cross sectional view showing a structure of a semiconductor chip 1, relating to a first embodiment of present invention;

FIG. 2 is a top view showing one example of wiring pattern of a metal wiring film 101;

FIG. 3 is a top view showing one example of wiring pattern of a metal wiring film 102;

FIG. 4 is a top view showing one example of an electrode 103;

FIG. 5 is a transition diagram illustrating a process for manufacturing the semiconductor chip 1;

FIG. 6 is a cross sectional view of the semiconductor chip 2, relating to modification example 1;

FIG. 7 is a cross sectional view of the semiconductor chip 3, relating to modification example 2;

FIG. 8 is a cross sectional view of the semiconductor chip 4, relating to modification example 3;

FIG. 9 is a cross sectional view of the semiconductor chip 5, relating to modification example 4;

FIG. 10 is a cross sectional view of an evaluation system 110;

FIG. 11 illustrates temperature profile measurement by the evaluation system 110 using a reflow furnace;

FIG. 12 illustrates temperature profile measurement by the evaluation system 110 not using the reflow furnace;

FIG. 13 illustrates temperature profile measurement by an evaluation system 120 in a three-dimensional lamination process;

FIG. 14 is a schematic diagram of an evaluation system 140;

FIG. 15 illustrates members which are used in the evaluation system 140;

FIG. 16 illustrates top views each showing an example of the semiconductor chip mounted on the evaluation system;

FIG. 17 is a cross sectional view of an evaluation system 140a;

FIG. 18 is a graph showing a result of evaluation regarding thermal property, according to the evaluation system 140a;

FIG. 19 is a cross sectional view of an evaluation system 140b;

FIG. 20 is a graph showing a result of evaluation regarding thermal property, according to the evaluation system 140b;

FIG. 21 is a cross sectional view of an evaluation system 140c;

FIG. 22 is a graph showing a result of evaluation regarding thermal property, according to the evaluation system 140c;

FIG. 23 is a graph showing a result of evaluation regarding thermal property, according to the evaluation system 140d;

FIG. 24 is a cross sectional view of a device chip 6, relating to a fourth embodiment of present invention;

FIG. 25 illustrates repairing of the device chip 6 mounted on a substrate 611; and

FIG. 26 is a schematic diagram of a rechargeable battery 700 incorporated in the device chip 6.

### DESCRIPTION OF THE PREFERRED EMBODIMENT

Hereinafter, the first embodiment of the present invention will be explained with reference to the accompanying drawings. It is to be noted that in the entire drawings, the same constitutional elements are labeled the same, and tedious explanations shall not be made as appropriate.

### <First Embodiment>

### (Semiconductor Chip)

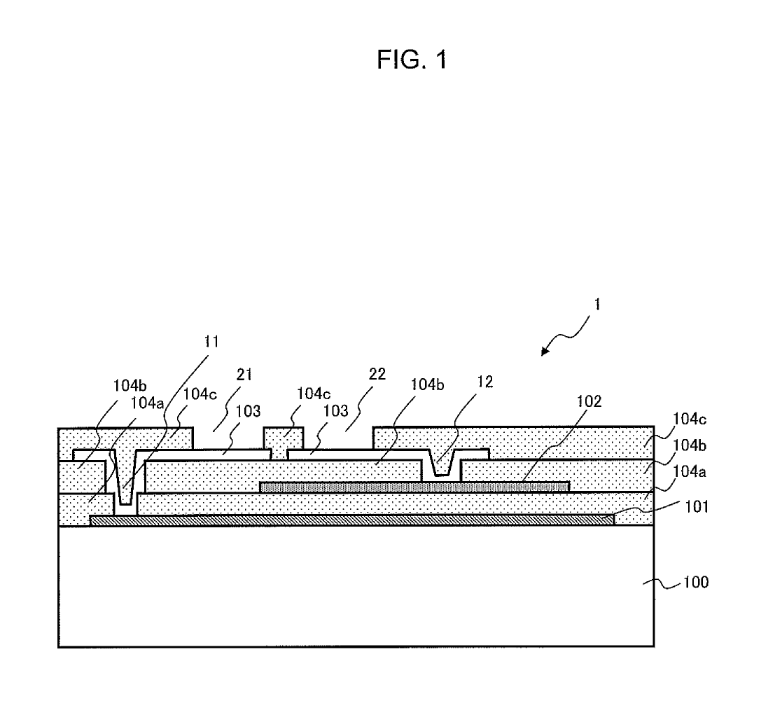

FIG. 1 is a cross sectional view showing the semiconductor chip 1 relating to the first embodiment of present invention.

The semiconductor chip 1 incorporates, sequentially laminating on one surface of a silicon substrate 100, a metal wiring film 101 serving as a resistance temperature detector, a polyimide film 104a serving as an insulation layer, a metal wiring film 102 serving as a heater, a polyimide film 104b serving as an insulation layer, an electrode 103 for electrically connecting the metal wiring film 101 and the metal wiring film 102 with a mount substrate, and a polyimide film 104c serving as a protection layer.

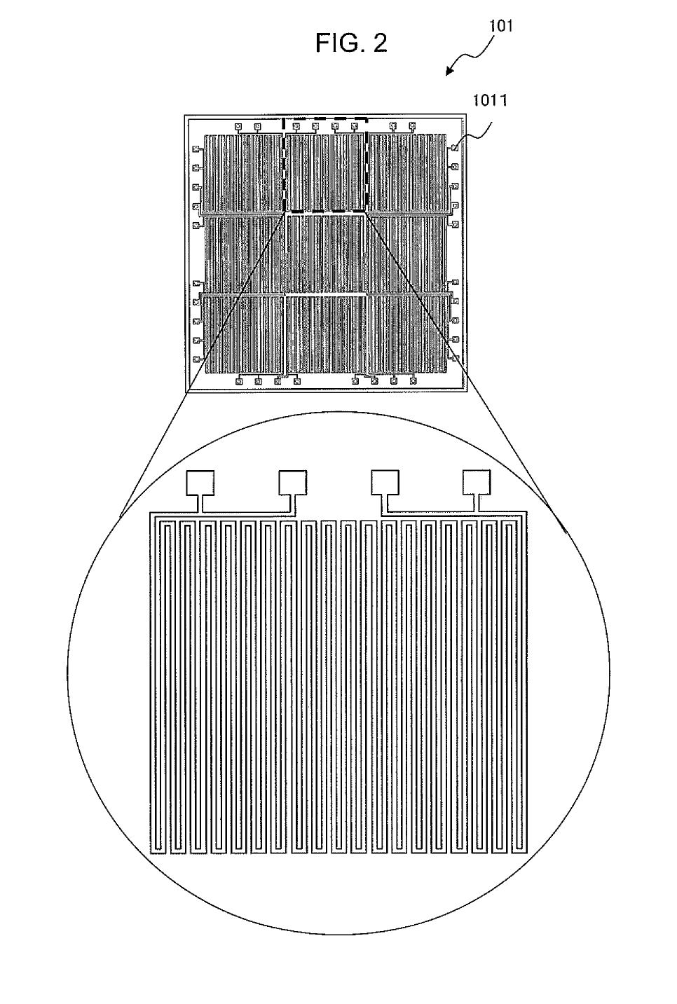

The metal wiring film 101 is a film on which a metal wiring pattern usable as the resistance temperature detector is formed. FIG. 2 illustrates one example of the wiring pattern of the metal wiring film 101. As shown in FIG. 2, on the metal wiring film 101, there are formed independent pieces of platinum wiring, winding in square shape, in respective regions being partitioned into 3×3 matrix form. Any number is applicable as the number of the partitioned regions, and its layout maybe in any manner, such as the regions being adjacent to each other as shown in FIG. 2, or alternatively separated from each other. Here, each of both ends of the platinum wiring are provided with two terminals 1011, four terminals in total, and those terminals 1011 are connected to the electrode 103. This configuration allows measurement of electric resistance on each wiring film according to so-called four-terminal method. In other words, it is possible to measure the temperature of platinum wiring in each of the regions, according to a platinum temperature coefficient of resistivity (3.9×10⁻³/K). Details will be described in the following.

It is to be noted here that the metal wiring film 101 is configured such that independent platinum wiring is provided in each region. However, it is also possible to configure such that the metal wiring film 101 is made up of one continuous wiring, or continuous wiring is made to branch out on the way and terminals are provided thereon.

Furthermore, as a metallic material used for the metal wiring film 101, it is desirable to employ platinum, in particular, since it is excellent in linearity between temperature and electric resistance. However, this is not the only example, and nickel, copper, or the like, may be usable too.

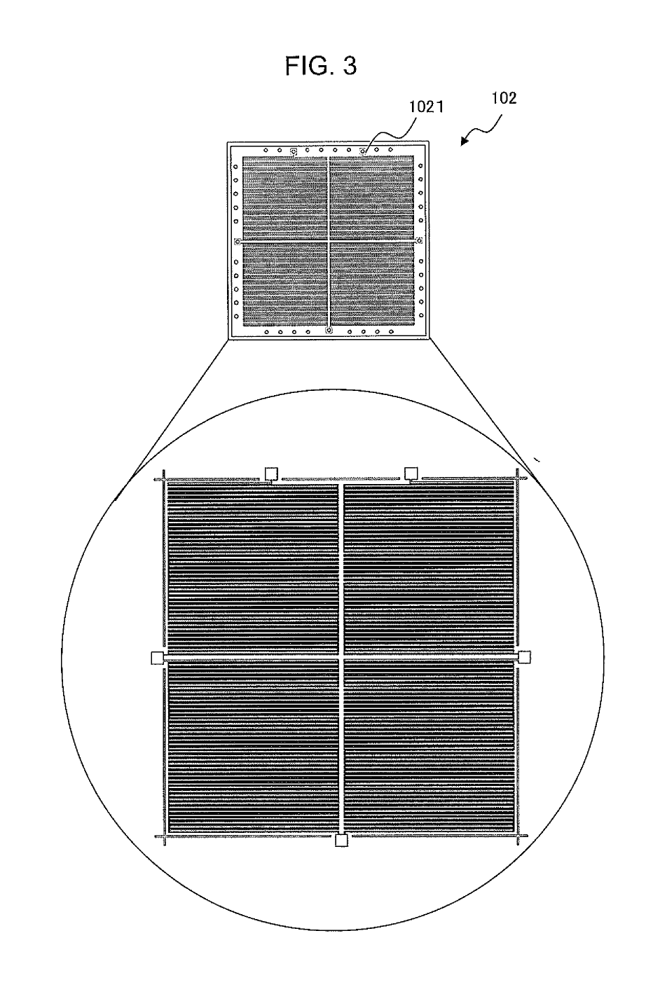

The metal wiring film 102 is a film on which a metallic wiring pattern usable as a heater is formed. FIG. 3 illustrates one example of the wiring pattern of the metal wiring film 102. As shown in FIG. 3, the metal wiring film 102 is a series of wiring pattern in which Ni wiring meanders in four regions partitioned on 2×2 matrix. The Ni wiring film has terminals 1021 on both ends and three on the way, and they are connected respectively with the electrodes 103, which are described in the following. When the region to be heated is partitioned, any number of the regions is applicable, and its layout may be in any manner, such as the regions being adjacent to each other as shown in FIG. 3, or alternatively separated from each other. This configuration as described above allows the Ni wiring regions to be heated in selectable manner.

It is to be noted that, according to this configuration, terminals are provided on the way, but it is further possible to configure such that the terminals are provided only on both ends. Alternatively, independent wiring may be provided in each of the partitioned regions, in the same manner as the metal wiring film 101.

In addition, the metallic material used for the metal wiring film 102 is not limited to those as described above. It is further possible to employ metal having high electric resistance, patterning characteristics, and high temperature durability, such as Ni—Cr based alloys, Ni—Cr—Al based alloys, Cu, Cu—Mn, Cu—Ni, Fe—Cr based alloys, and tungsten.

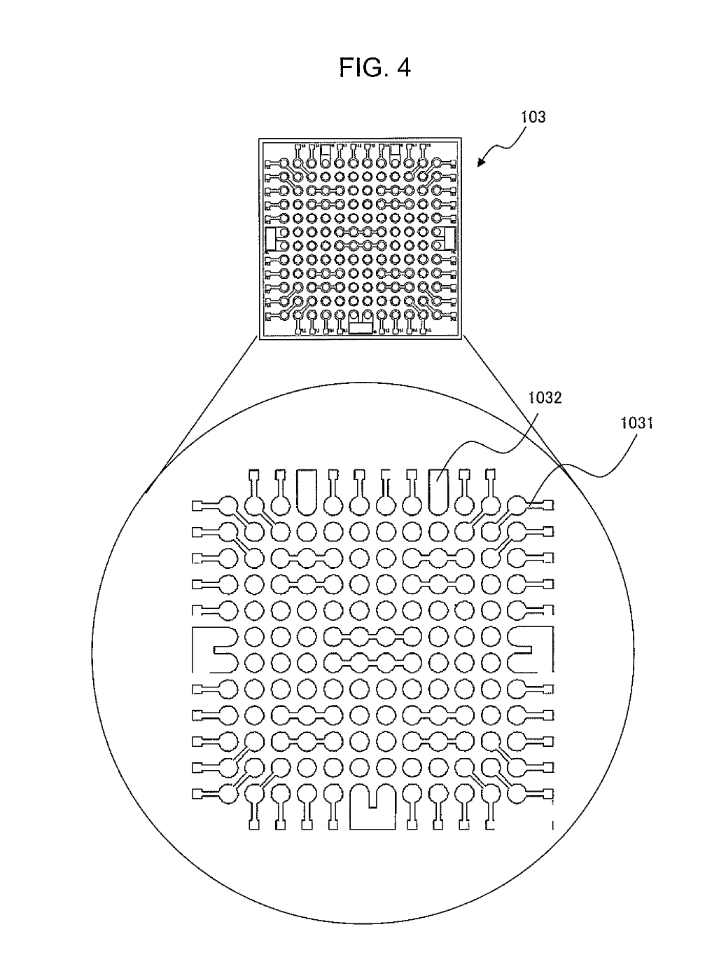

FIG. 4 illustrates one example of the electrode 103. The electrode 103 is an electrode used for external connection, being electrically connected with both the metal wiring film 101 and the metal wiring film 102. Here, an electrode for external connection use 1031 is connected to the terminal 1011 of the metal wiring film 101, and an electrode for external connection use 1032 is connected to the terminal 1021 of the metal wiring film 102.

On the electrode 103, there is formed the polyimide film 104c serving as the protection layer. On the polyimide film 104c, there are provided an aperture 21 and an aperture 22, the aperture 21 being used for connecting the electrode 103 (metal wiring film 101) with a substrate 111 and other semiconductor chip described below, and the aperture 22 being used for connecting the electrode 103 (metal wiring film 102) with the substrate 111.

Furthermore, as insulation layers, the polyimide film 104a is provided between the metal wiring film 101 and the metal wiring film 102, and the polyimide film 104b is provided between the metal wiring film 102 and the electrode 103. The polyimide films 104a and 104b are provided with an aperture 11 for connecting the metal wiring film 101 and the electrode 103, and the polyimide film 104b is further provided with an aperture 12 for connecting the metal wiring film 102 and the electrode 103.

Mounting the semiconductor chip 1 as described above on the mount substrate allows evaluation of various temperature processes.

### (Production Method of Semiconductor Chip)

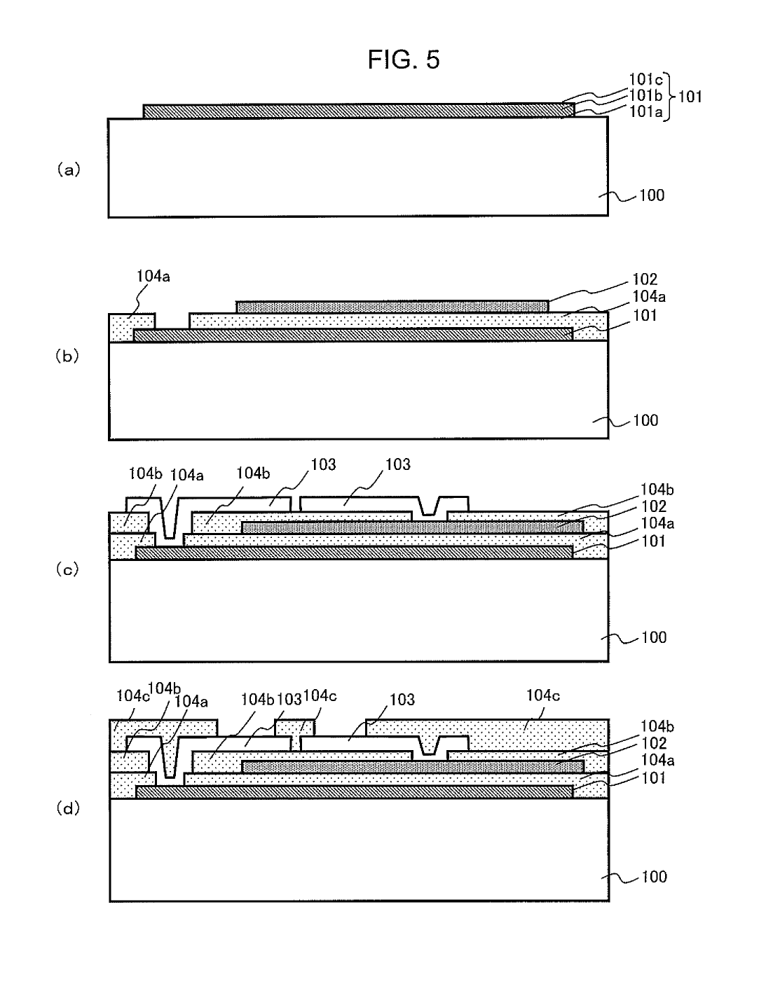

Next, with reference to FIG. 5(a) to FIG. 5(d), a method for manufacturing the semiconductor chip 1 will be explained. The figures from FIG. 5(a) to FIG. 5(d) are transition diagrams showing a process of the method for manufacturing the semiconductor chip 1 relating to the first embodiment of the present invention.

(a) Firstly, a silicon oxide film, not illustrated, is made to grow on one surface of the silicon substrate 100. The silicon oxide film may be formed by a general method, such as allowing silicon to react with oxygen under steam atmosphere at approximately 900° C. Then, the metal wiring film 101 having platinum wiring patterns is formed on the silicon oxide film according to lift-off method. Specifically, a resist subjected to patterning is formed on the silicon oxide film, and PtO film 101a, Pt film 101b, and TiO film 101c are sequentially deposited thereon. Then, the resist is removed, thereby completing the wiring pattern as shown in FIG. 2.

It is to be noted that in order to enhance adhesiveness between the PtO film 101a with the silicon oxide film, and between the TiO film 101c with the polyimide film 104a, each film is set on the Pt film 101b with about one-hundredth film pressure.

(b) Next, the polyimide film 104a approximately 5 μm in film thickness is formed as the insulation layer. The polyimide film 104a is configured to cover both ends of the metal wiring film 101 and, in the middle of the polyimide film 104a, a portion corresponding to the terminal 1011 is opened. Then, on the polyimide film 104a, there is formed the metal wiring film 102 having the Ni wiring pattern. By way of example, a semi-additive process to conduct resist photolithography and Ni electroplating at the same time by using a film laminating Cr film and Cu film as a seed film is employed, thereby forming the metal wiring film 102 having the wiring pattern as illustrated in FIG. 3.

(c) Furthermore, the polyimide film 104b which covers both ends of the metal wiring film 102 and is provided with apertures at the portions corresponding to the terminal 1011 and the terminal 1021, is formed, and on the polyimide film 104b, there is formed the electrode 103 for external connection use, which is illustrated in FIG. 4, according to the semi-additive process.

(d) Finally, the polyimide film 104c which is provided with apertures to connect the mount substrate and the like described below with the electrode 103, serving as the protection layer, is formed and thereby obtaining semiconductor chip 1 illustrated in FIG. 1.

It is to be noted that the present invention is not limited to the semiconductor chip relating to the first embodiment described above, and various modifications are possible within the scope of the technical idea of the present invention.

By way of example, the resistance temperature detector and the heater may be arranged in any layout.

It is further possible to form the resistance temperature detector, the heater, and the electrode in an identical plane (the same layer) of the silicon substrate.

Furthermore, if the relationship between temperature and electric resistance of the wiring film is clarified, it is possible to use one wiring both for the heater and the resistance temperature detector. In other words, if the electric resistance is measured simultaneously with supplying power from the power source connected to the wiring, the temperature of the wiring itself which generates heat can be measured, without installing additional wiring separately. With this configuration, it is possible to drastically simplify the structure of the semiconductor chip of the present invention.

Here, it is further possible to configure such that only the metal wiring film 101 is provided serving as the resistance temperature detector, without setting the heater function. By way of example, if the temperature profiling is carried out for the process to apply heat from the outside, the heater is not necessarily required, and thus achieving a more simplified configuration. It is a matter of course to provide only the metal wiring film 102 as the heater, and the temperature maybe measured by the thermocouple, or the like.

Hereinafter, modification examples of the semiconductor chip of the present invention will be described specifically.

### (Modification 1)

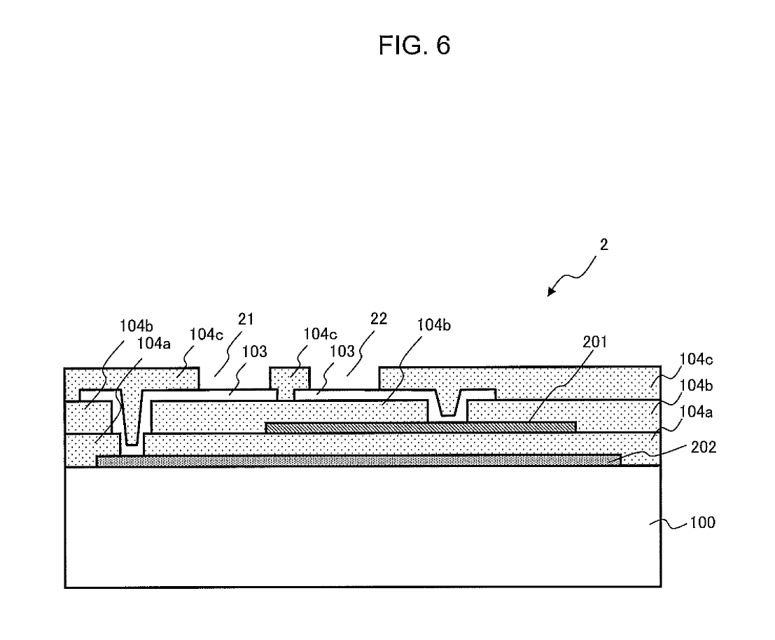

FIG. 6 is a cross sectional view showing a semiconductor chip 2 relating to the first modification example of the present invention. In the semiconductor chip 2, the metal wiring film 201 serving as the resistance temperature detector and the metal wiring film 202 serving as the heater are arranged at reversed locations, compared to the example of the semiconductor chip 1 which incorporates the resistance temperature detector (metal wiring film 101) and the heater (metal wiring film 102).

According to the semiconductor chip 2 with such configuration as described above, a measurement area of the metal wiring film 201 serving as the resistance temperature detector is placed closer to the apertures 21 and 22 through which the electrode 103 connected externally. Therefore, it is possible to accurately measure the temperature of the position closer to the heat source (e.g., underfill material).

### (Modification 2)

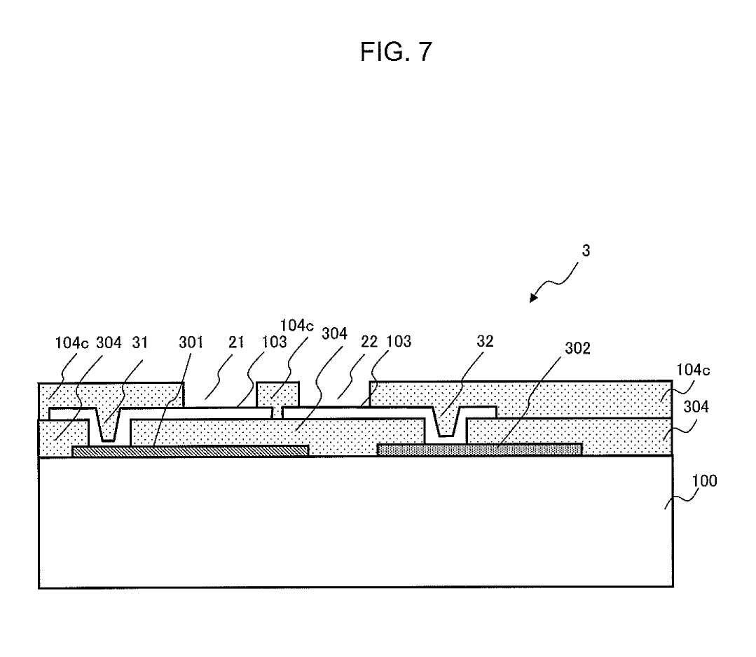

FIG. 7 is a cross sectional view showing a semiconductor chip 3 relating to the second modification example of the present invention. In the semiconductor chip 3, the metal wiring film 301 serving as the resistance temperature detector and the metal wiring film 302 serving as the heater are formed on the oxide film in the same plane, and a polyimide film 304 is provided, having apertures 31 and 32 in such a manner as covering both ends of the metal wiring film 301 and the metal wiring film 302, the aperture 31 being used for connecting the metal wiring film 301 with the electrode 103 and the aperture 32 being used for connecting the metal wiring film 302 with the electrode 103.

With this configuration, one polyimide film 304 functions as two polyimide films (polyimide film 104a and polyimide film 104b) serving as the insulation layers. Therefore, the number of layers is decreased compared to the semiconductor chip 1, and it is possible to manufacture the semiconductor chip at a lower cost according to this simpler method.

### (Modification 3)

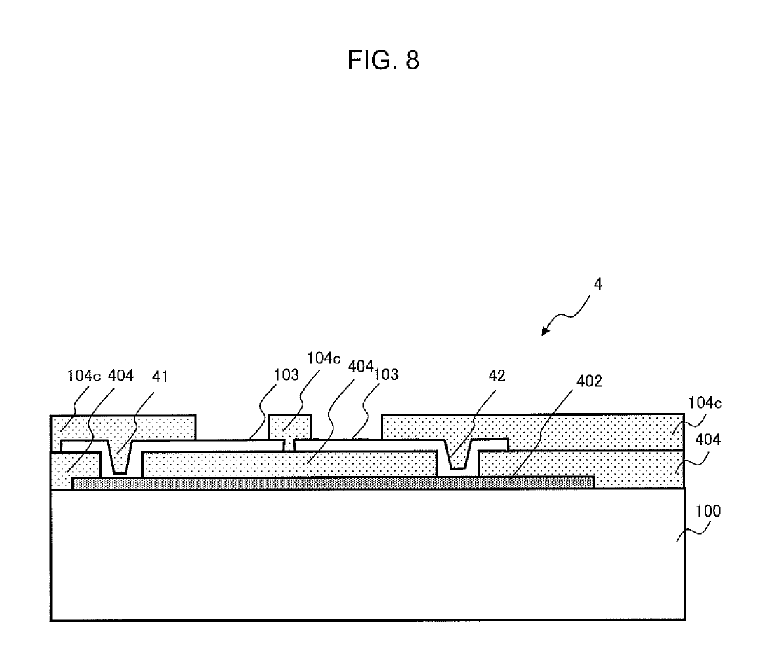

FIG. 8 is a cross sectional view showing a semiconductor chip 4 relating to the third modification example of the present invention. In the semiconductor chip 4, there is formed only the metal wiring film 402 functioning as both the resistance temperature detector and the heater, and a polyimide film 404 is provided in such a manner as covering both ends of the metal wiring film 402, having apertures 41 and 42 for connecting the metal wiring film 402 with the electrode 103. For example, as shown in FIG. 2, Ni wiring can be employed as the metal wiring film 402. This semiconductor chip 4 is mounted on the substrate 111 described in the following, and both ends of the substrate are connected to the power source and the voltmeter. Accordingly, it is possible to control current flowing through the Ni wiring and measure the temperature in each region of the Ni wiring, based on the Ni temperature coefficient of resistivity (6.3 K×10⁻³/K). Cu wiring may be usable, for instance, instead of the Ni wiring. For that case, Cu temperature coefficient of resistivity (4.3×10⁻³/K) is employed.

According to the semiconductor chip 4 with such a configuration as described above, one more polyimide film and one more metal wiring film are not required, compared to the semiconductor chip 1, and therefore, the manufacturing process is simplified, reducing the manufacturing cost drastically.

### (Modification 4)

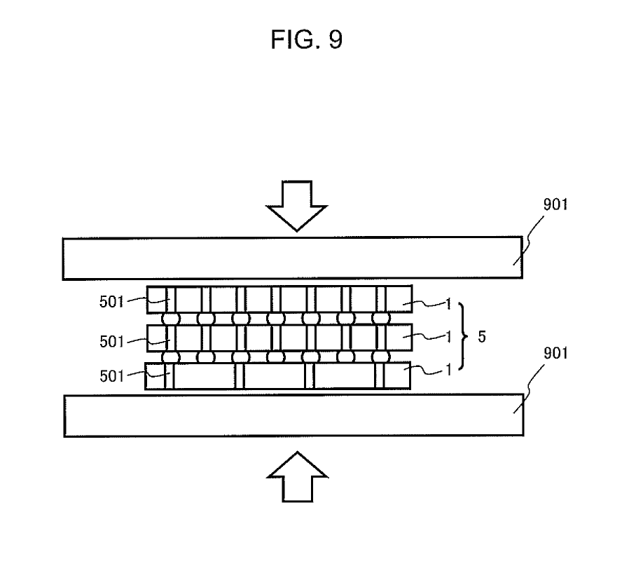

FIG. 9 is a cross sectional view showing a semiconductor chip 5 relating to the fourth modification example of the present invention. The semiconductor chip 5 is a three-dimensional lamination chip, which is obtained by laminating multiple semiconductor chips 1. It is possible to manufacture the semiconductor chip 5, for example, by forming a through-hole 501 on a pad area of each of the semiconductor chips 1 to bring them into conduction, and press-bonding them by a high-temperature pressing hot-press machine 901.

According to the semiconductor chip 5 with such a configuration as described above, it is possible to evaluate the temperature process of the semiconductor chip having the three-dimensionally laminated structure.

### <Second Embodiment>

### (Evaluation System)

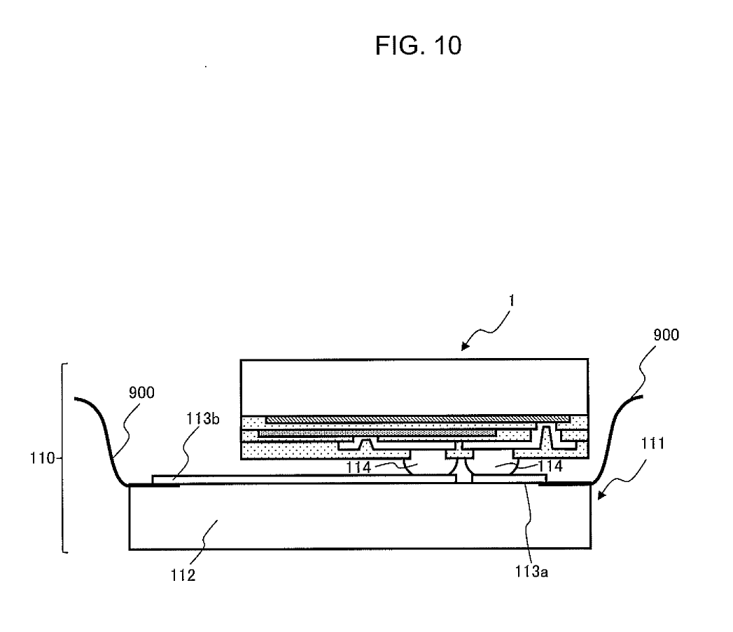

Next, an evaluation system 110 relating to a second embodiment of present invention will be explained. FIG. 10 is a cross sectional view of the evaluation system 110 in which the semiconductor chip 1 is mounted on the substrate 111.

The evaluation system 110 is obtained by mounting the semiconductor chip 1 via solder balls 114 on the substrate 111 such as a printed circuit board and a ceramic board, which is made up of silicon chip 112. The substrate 111 is provided with a substrate wiring 113a being connected to the metal wiring film 101 serving as the resistance temperature detector, and a substrate wiring 113b being connected to the metal wiring film 102 serving as the heater. A group of wiring 900 establishes wire connection via the substrate wiring 113a, between the metal wiring film 101 being the resistance temperature detector, and an ammeter and a voltmeter not illustrated, and the group of wiring 900 further establishes wire connection via the substrate wiring 113b, between the metal wiring film 102 being the heater and an external power source not illustrated. The configuration above enables heating of the metal wiring film 102, and measurement of electric resistance in each of the regions of the metal wiring film 101 by using the four-terminal method. According to the measurement result and the platinum temperature coefficient of resistivity (3.9×10⁻³/K), it is possible to measure temperature in each of the regions of the platinum wiring.

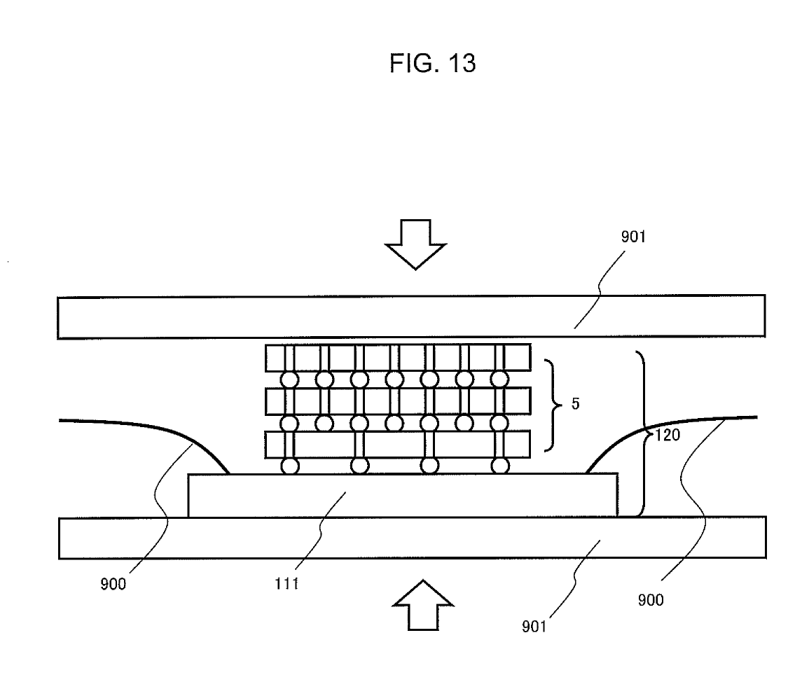

It is to be noted that a shape of the semiconductor chip used in the evaluation system is not limited to the composition as described above. For example, the semiconductor chip 5 as illustrated in FIG. 9 may be mounted on the substrate 111, thereby forming the evaluation system 120 as illustrated in FIG. 13.

Evaluations of the mounting process, utilizing the evaluation system as described above, will be explained in the following.

### (Evaluation of Mounting Process 1)

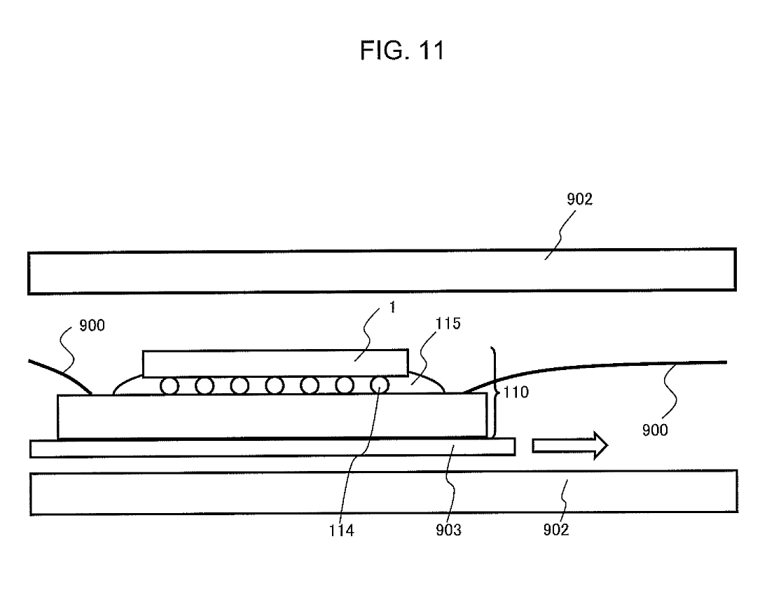

FIG. 11 illustrates temperature profile measurement of the mounting process according to the evaluation system 110 which uses a reflow furnace. Mounting of the semiconductor chip is carried out via a soldering process using the reflow furnace. There are significant temperature differences; among the set temperature within the reflow furnace, the temperature of the surfaces of the semiconductor chip and the substrate, and the temperature of the solder balls. Therefore, as shown in FIG. 11, if the evaluation system 110 is provided in the soldering process, it is possible to evaluate the temperature variation inside the semiconductor chip.

Specifically, the semiconductor chip 1 is placed on a moving stage 903 within the reflow furnace 902, to be heated therein. Then, changes of electric resistance in each of the regions in the metal wiring film 101 are monitored, thereby obtaining the temperature profile in proximity to the solder balls 114 and the underfill material 115.

### (Evaluation of Mounting Process 2)

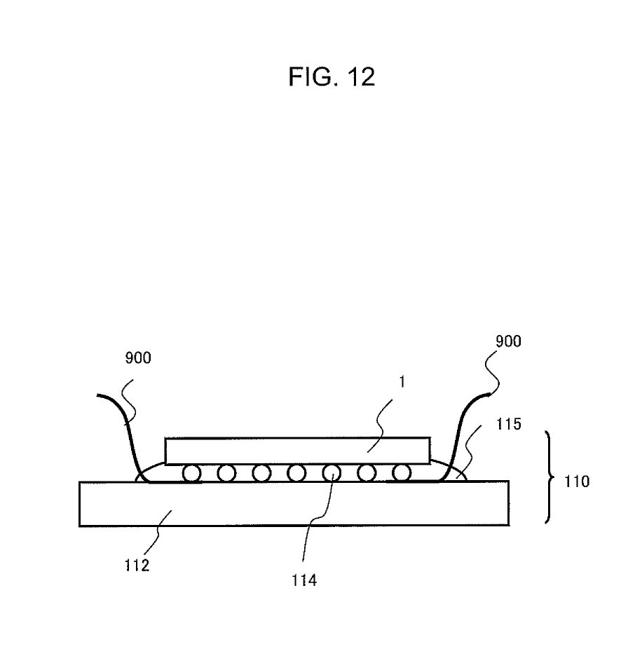

FIG. 12 illustrates the temperature profile measurement of the mounting process according to the evaluation system 110 which does not use the reflow furnace.

In the present embodiment, the power supplied to the metal wiring film 102 is controlled according to the temperature profile of the solder process, which is obtained by the procedure above. Then, the temperature of the heater is made to change over time, and the state in the reflow furnace is reproduced. Consequently, this enables to obtain the temperature profile during the process, even though the reflow furnace is not used.

As thus described, controlling of the heater temperature also enables reproduction of thermal curing of the semiconductor chip 1 and the underfill material 115, and enables observation of the temporal change of the underfill material during the curing by stopping the heating in midstream. Therefore, it is possible to acquire data usable for developing each material.

### (Evaluation of Mounting Process 3)

FIG. 13 illustrates the temperature profile measurement by an evaluation system 120 in the three-dimensional lamination process.

As explained in the fourth modification example described above, the semiconductor chip 5 being three-dimensionally laminated is manufactured, by accumulating multiple semiconductor chips 1, and pressed and heated by the high-temperature pressing hot-press machine 901. Here, the evaluation system 120 mounting the semiconductor chip 5 on the substrate 111 is subjected to the three-dimensional lamination process, thereby measuring the temperature profile during the process.

The group of wiring 900 establishes wire connection between each metal wiring film 101 of each of the semiconductor chips 1 constituting the semiconductor chip 5, and the ammeter/voltmeter not illustrated. Therefore, it is possible to observe a specific type of temperature variation being seen in any specific region of any specific semiconductor chip being laminated.

It is surely possible to allow the group of wiring 900 to establish wire connection between the metal wiring film 102 being the heater of each of the semiconductor chips and the external power source, and change the temperature of the heater according to the temperature profile of the three-dimensional lamination process obtained in the above procedure, thereby reproducing the three-dimensional lamination process without using the high-temperature pressing hot-press machine.

### <Third Embodiment>

### (Evaluation System)

Next, an explanation will be made as to evaluation of thermal property according to the evaluation system relating to the third embodiment of the present application. The evaluation system relating to the present embodiment enables acquisition of thermal property of the semiconductor chip and surrounding materials thereof, by installing the evaluation system relating to the second embodiment in a more practical style.

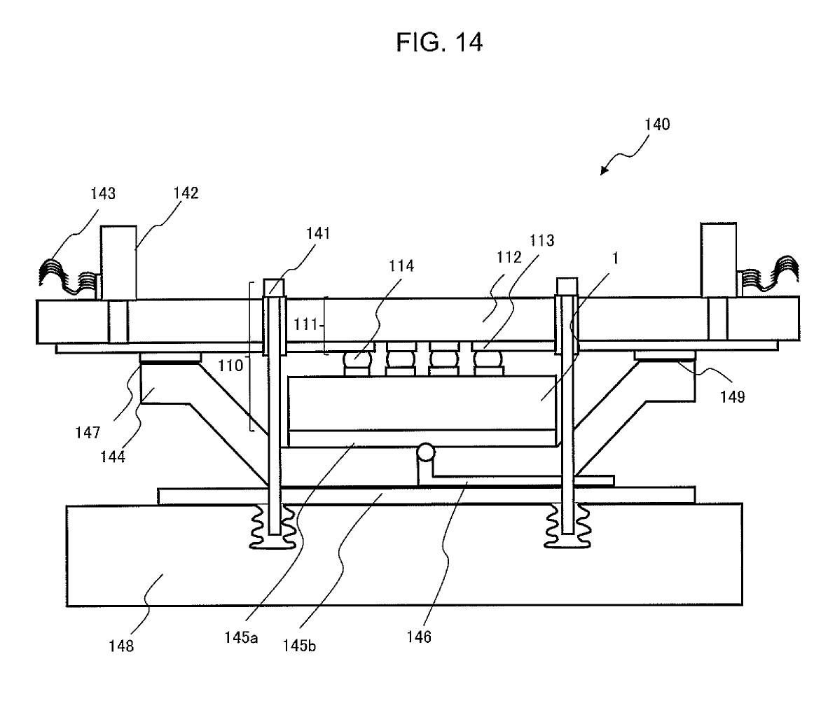

FIG. 14 is a schematic diagram illustrating an evaluation system 140 of the present invention.

Specifically, the evaluation system 140 incorporates the evaluation system 110 and a heat sink 148 made of aluminum material, and the like, placing a thermally conductive sheet 145a, a heat spreader 144, and a thermally conductive sheet 145b, between the evaluation system 110 and the heat sink 148 in this order, and they are fixed via resin screws 142. The heat spreader 144 is connected to the substrate wiring 113 via a sealing member 149. The heat spreader 144 is provided with a thermocouple 146 at a position below the semiconductor chip 1. It is to be noted that wiring of the substrate 111 is pulled out as a harness 143, to the outside via the connector 142.

According to this evaluation system 140, temperature variation of the resistance temperature detector provided in the semiconductor chip 1 and temperature variation of the thermocouple 146 are obtained, so that it is possible to evaluate thermal property similar to the thermal property appeared at the time when a semiconductor chip is actually mounted. Furthermore, a temperature difference between the resistance temperature detector and the thermocouple is calculated, and thermal property (electric resistance) of the thermally conductive sheet 145a are gained. Therefore, it is possible to acquire data which is usable also for development of thermally conductive materials such as thermally conductive sheet.

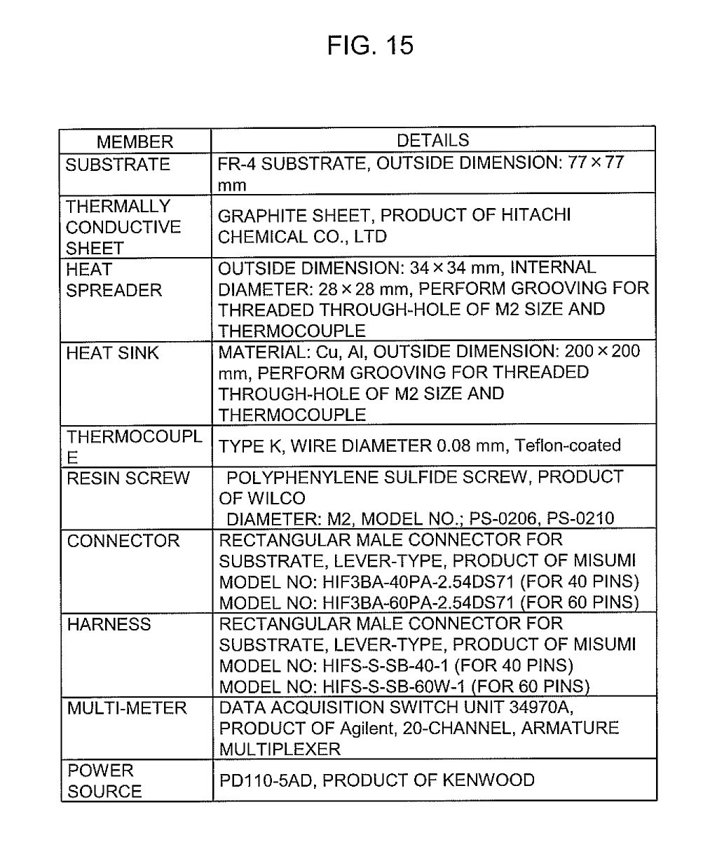

It is to be noted that this evaluation system 140 may be made up of members as shown in FIG. 15, for instance.

An example of the semiconductor chip mounted on the evaluation system may be as the following.

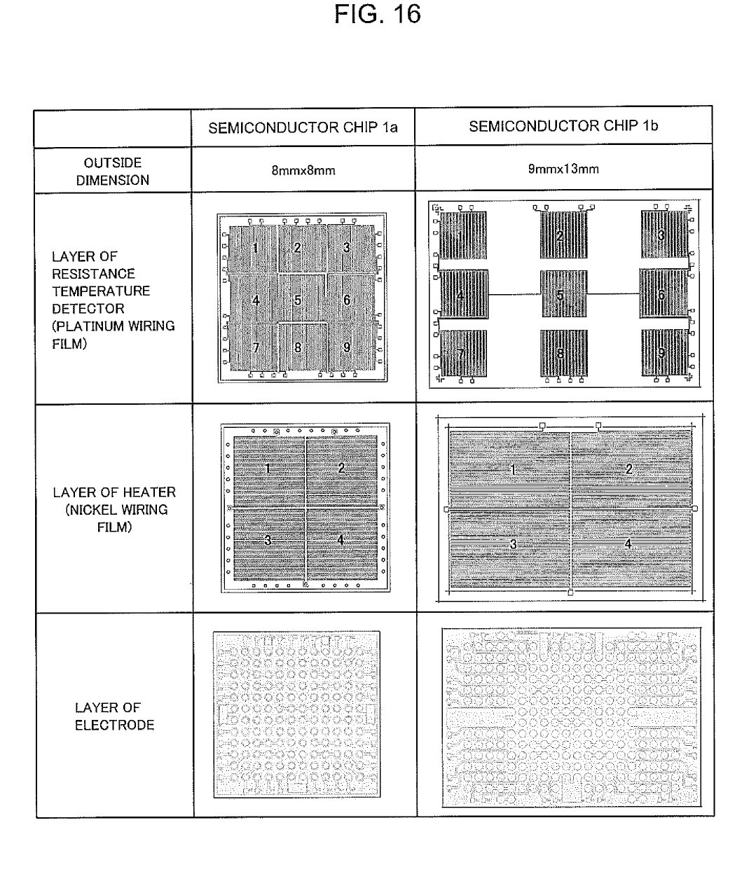

FIG. 16 illustrates top views showing a combination of the metal wiring film serving as a resistance temperature detector, a metal wiring film serving as a heater, and an electrode, which are formed on the two types of semiconductor chips 1a and 1b.

The semiconductor chip la has the outside dimension of 8 mm×8 mm, accumulating the metal wiring film 101a in which regions partitioned in matrix of 3×3 are arranged being adjacent to one another, the metal wiring film 102a in which regions partitioned in matrix of 2×2 are arranged being adjacent to one another, and the electrode 103a covering all over the area corresponding to the outside dimension. The semiconductor chip 1b has the outside dimension of 9 mm×13 mm, accumulating the metal wiring film 101b in which regions partitioned in matrix of 3×3 are separated from one another, the metal wiring film 102b in which regions partitioned in matrix of 2×2 are arranged being adjacent to one another, and the electrode 103b covering all over the area corresponding to the outside dimension. It is to be noted here that the area of the regions of the metal wiring film 101b is identical to that of the metal wiring film 102b.

Hereinafter, there will be shown examples of the thermal property evaluation according to the evaluation system relating to the third embodiment of the present invention, and the present invention will be explained more specifically. It is to be noted that the present invention is not restricted by those examples.

### Example 1

### Evaluation of Temperature Measurement

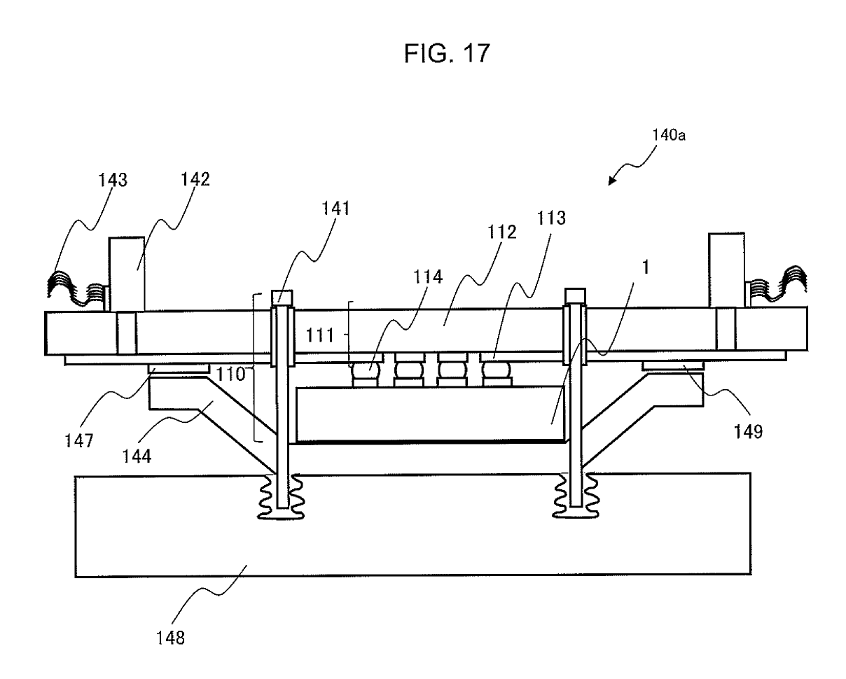

FIG. 17 is a cross sectional view of the evaluation system 140a relating to the first example of the present invention. The evaluation system 140a is different from the evaluation system 140, in the point that this configuration is provided with neither the thermally conductive sheets 145a and 145b, nor the thermocouple 146. It is to be noted that in this example here, members illustrated in FIG. 15 were employed, and the semiconductor chip lb described above was employed as the semiconductor chip mounted on the evaluation system 110.

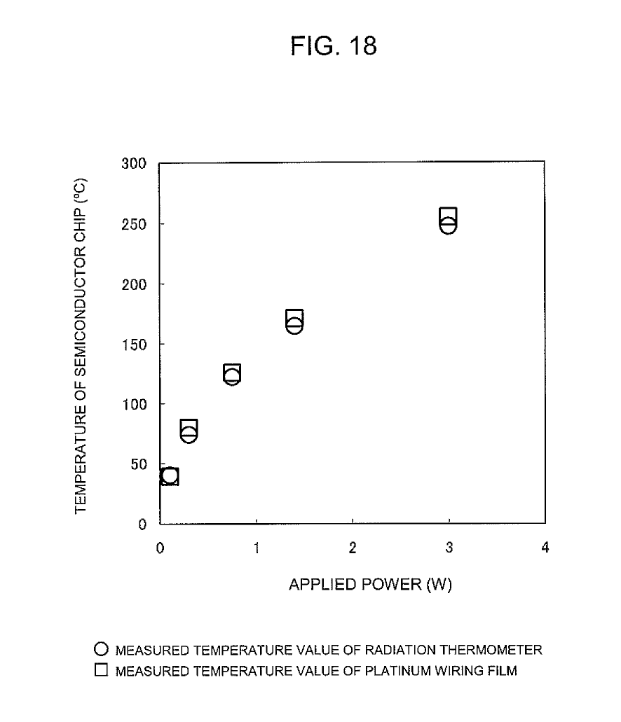

In the present example, power was applied to the semiconductor chip lb to heat the metal wiring film 102b, and simultaneously the temperature of the semiconductor chip lb was measured by the metal wiring film 101b, and also by a radiation thermometer (product of testo Inc., testo 830T3) which was prepared separately, thereby evaluating temperature sensing capability of the evaluation system 140a. FIG. 18 illustrates the result of the evaluation.

FIG. 18 is a graph showing measured temperature values (□) according to the metal wiring film 101b, and measured temperature values (o) measured by using the radiation thermometer, with respect to the power applied to the semiconductor chip 1b. It is to be noted that the measured temperature values (□) according to the metal wiring film 101b indicate the temperature in the measurement area 1 (see FIG. 16). The measured temperature values (o) according to the radiation thermometer are values obtained by measuring the temperature in the measurement area 1 of the semiconductor chip lb (see FIG. 16).

As seen from FIG. 18, there is little difference between the measured temperature value (□) according to the metal wiring film 101b and the measured temperature value (o) measured by using the radiation thermometer, and there is good agreement therebetween. Consequently, it has been found that according to the evaluation system of the present invention, the variation of temperature caused by heat generation from the metal wiring film 102b can be measured accurately according to the metal wiring film 101b without using the thermocouple.

### Example 2

### Evaluation of Temperature Measurement by Region

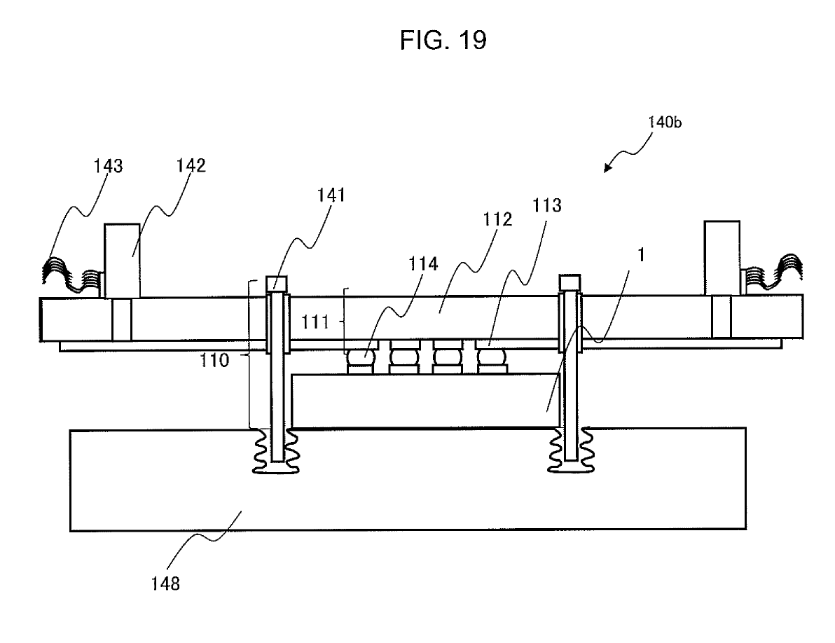

FIG. 19 is a cross sectional view of the evaluation system 140b relating to the second example of the present invention. The evaluation system 140b has a structure different from the evaluation system 140a, in the point that it does not employ the heat spreader 144. It is to be noted that in this example here, members illustrated in FIG. 15 were employed, and the semiconductor chip lb described above was employed as the semiconductor chip mounted on the evaluation system 110.

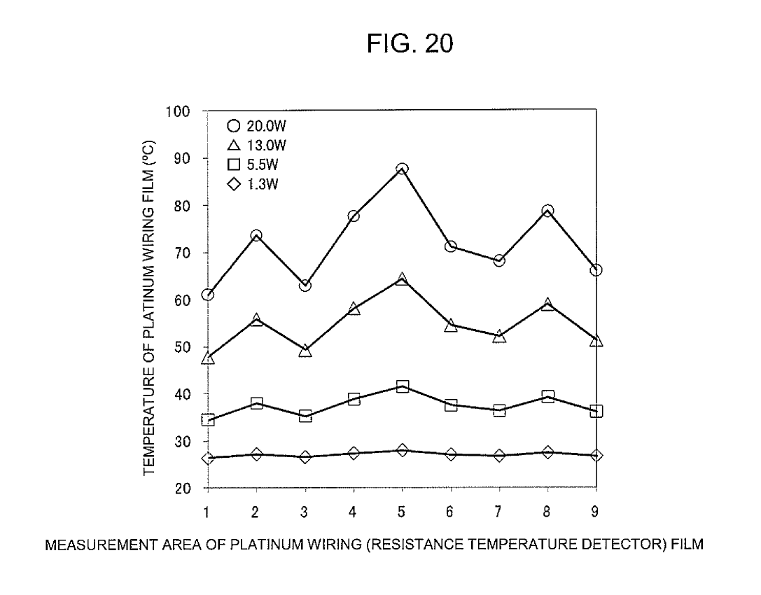

In the present example, power was applied to the semiconductor chip lb to heat the metal wiring film 102b, simultaneously measuring the temperature of all the measurement areas 1 to 9 in the platinum wiring layers according to the metal wiring film 101b (see FIG. 16). FIG. 20 shows the result thereof.

FIG. 20 is a graph showing the measured temperature values in the respective measurement areas, when the power applied to the semiconductor chip 1b was 1.3 W (⋄), 5.5 W (□), 13.0 W (Δ), and 20.0 W (o).

As seen from FIG. 20, as the power applied to the semiconductor chip 1b became higher, the temperature values in the respective measurement areas rose accordingly. If observed in each measurement area, the temperature in the measurement area 5 at the center of the semiconductor chip is the highest in all of the fields. On the other hand, the temperature values in the measurement areas 1, 3, 7, and 9 respectively at the edges of the semiconductor chip were relatively low. This tendency became more conspicuous as the applied power became higher. These results indicate that heat is apt to be remained in the center of the semiconductor chip, whereas heat is apt to escape easily at the edge side thereof. With the result, it is found that according to the present invention, temperature variation due to the heat generation from the metal wiring film 102b can be accurately measured with respect to each region of the metal wiring film 101b.

As thus described, according to evaluation system of the present invention, it is possible to reproduce the heating structure of a real package, and simultaneously obtain an accurate temperature profile of its exothermal behavior (thermal property) as to each region.

### Example 3

### Evaluation of Temperature Measurement With or Without the Thermally Conductive Sheet

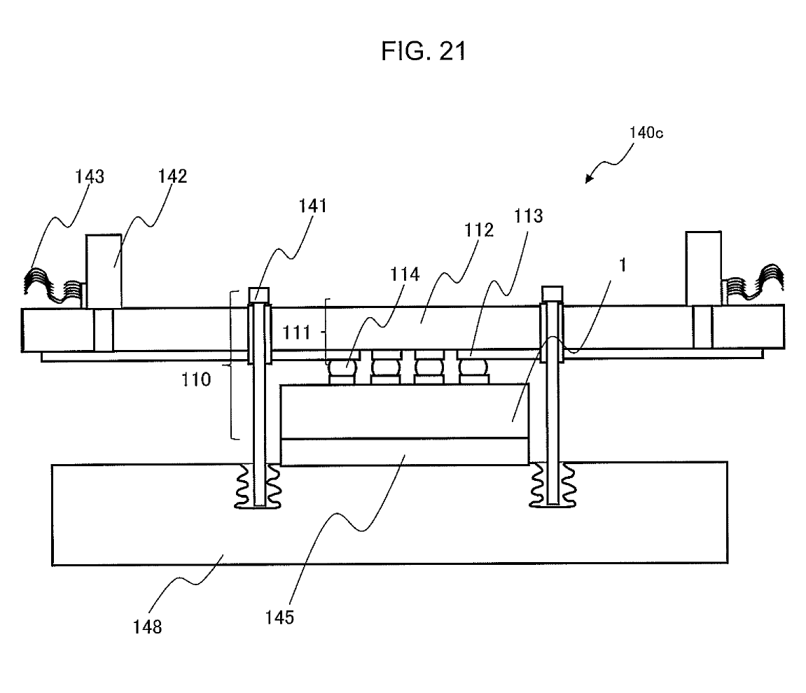

FIG. 21 is a cross sectional view of the evaluation system 140c relating to the third example of the present invention. The evaluation system 140c is different from the evaluation system 140a in the point that the evaluation system 140c does not use the heat spreader 144. Temperature was measured also for the case the thermally conductive sheet 145 was used as the thermally conductive material, instead of the heat spreader 144. It is to be noted that in this example here, members illustrated in FIG. 15 were employed, and the semiconductor chip la described above was employed as the semiconductor chip mounted on the evaluation system 110.

In the present example, temperature was measured as to all the measurement areas 1 to 9 (see FIG. 16) in the platinum wiring layer according to the metal wiring film 101a, for both the case where the thermally conductive sheet 145 was used and the case where it was not used, in the evaluation system 140c. It is to be noted that the power applied to the semiconductor chip la was kept constant.

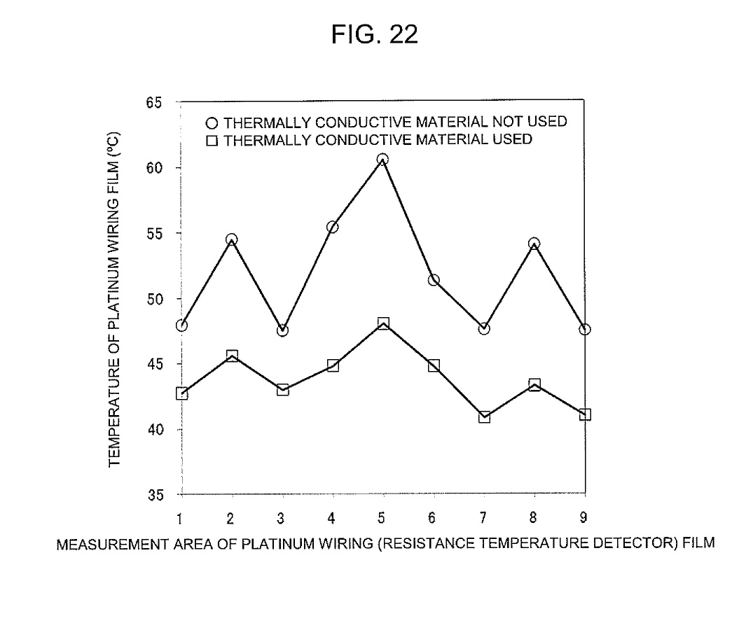

FIG. 22 is a graph showing the result of temperature measurement (□) in each of the measurement areas 1 to 9 when the thermally conductive sheet 145 was used, and the result of temperature measurement (o) in each of the measurement areas 1 to 9, when the thermally conductive sheet 145 was not used, in the case where the power applied to the semiconductor chip 1a was 15W.

As seen from FIG. 22, it has been found that the result of the temperature measurement (□) when the thermally conductive sheet was provided between the semiconductor chip and the heat sink was lower than the result of temperature measurement (o) when the thermally conductive material was not used, with respect to all of the regions. These results indicate that the heat generated in the semiconductor chip was efficiently conducted to the thermally conductive sheet, by using the thermally conductive material with a high thermal conductivity. It is further found that the temperature distribution among each of the measurement areas is restrained. This result indicates that enhancement of adhesiveness between the semiconductor chip la and the thermally conductive sheet reduced contact resistance, and the heat generated in the semiconductor chip la was efficiently dissipated and conducted in the plane.

As thus described, according to the evaluation system of the present invention, it is possible to evaluate thermal property and its effect, with respect to each member such as the thermally conductive material.

### Example 4

### Evaluation of Temperature Measurement According to Heat Cycle Test

In the present example, the evaluation by an evaluation system 140d is carried out by measuring the temperature in all the measurement areas 1 to 9 (see FIG. 16) under the condition of constant power application, before and after the heat cycle test as described below. The evaluation system 140d simply employed the semiconductor chip 1b, instead of the semiconductor chip la of the evaluation system 140c, and therefore the figure is omitted.

The heat cycle test was conducted by repeating the following condition for 180 cycles; firstly, the temperature was kept to −40° C. for 15 minutes, then the temperature within the test area was made to rise up to +125° C. in one minute, thereafter maintaining the temperature for 15 minutes, and again, the temperature was made to drop to −40° C. in one minute, thereafter maintaining the temperature for 15 minutes. It is to be noted that ETAC NT1530W was used as the heat cycle testing unit.

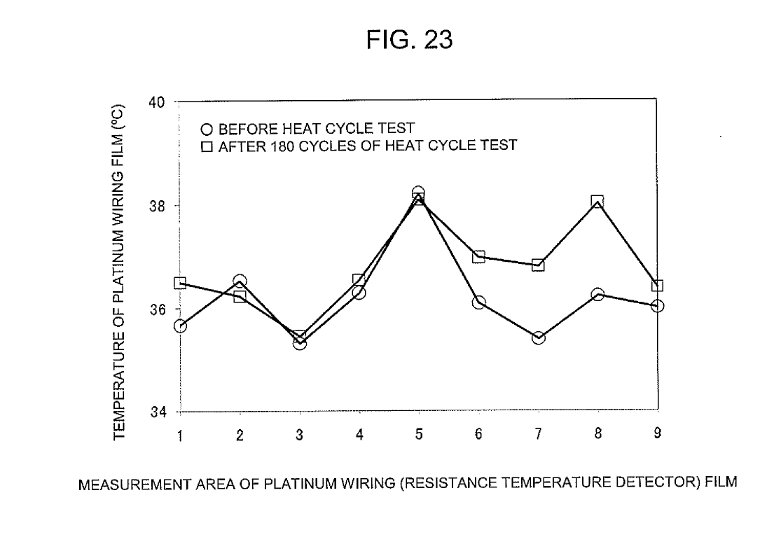

FIG. 23 is a graph showing the result of temperature measurement (o) in each of the measurement areas 1 to 9, before the heat cycle test was conducted, and the result of temperature measurement (□) after the heat cycle test was conducted, under the condition that the power applied to the semiconductor chip 1b was 20 W.

As shown in FIG. 23, in the measurement areas 2 to 5, there was little difference between the temperature measurement results before and after the heat cycle test. On the other hand, in the measurement areas 1, and 6 to 9, it has been found that the temperature after the heat cycle test was conducted was higher than before the heat cycle test was conducted. Causes of the above results are conceivable as the following; due to the load by the heat cycle test, warpage might occur on the substrate or on the semiconductor chip, or adhesiveness with the thermally conductive sheet might be deteriorated, and accordingly, the thermal conduction efficiency was down in the measurement areas 1 and 6 to 9.

As thus described, according to the evaluation system of the present invention, heat dissipation behavior of the thermally conductive material mounted on the package is made visible in a reliability test such as the heat cycle test, and simultaneously it is possible to evaluate the thermal property of the thermally conductive material under actual usage environment.

The semiconductor chip and the evaluation system thereof according to the present invention have been explained so far.

In the present invention, since the heater simulates the semiconductor device which is a heat source of the semiconductor chip, the resistance temperature detector is allowed to measure the temperature at a position several micrometers to tens of micrometers away from the heat source. In addition, the temperature profile of the joint between the semiconductor chip being the heat source and the substrate is accurately measured, thereby achieving optimization of junction process and obtaining data which is extremely significant for developing a junction material.

For example, in a high temperatures and high humidity test, constitutional elements are exposed to high temperature in a testing tank to evaluate resistance of the constitutional elements. Therefore, it has been difficult to reproduce the situation where a mounted semiconductor chip in effect generates heat from the inside. However, according to the present invention, it is possible to directly heat the semiconductor chip by the heater, and more accurate temperature profile can be obtained compared to the conventional method which heats the inside of the testing tank.

It is further possible to drastically reduce thermal capacity and the temperature of the semiconductor chip can be controlled within a short period of time. Therefore, this may largely shorten the time required for heating and cooling, particularly in the heat cycle test. Byway of example, if it takes 30 minutes for each of heating and cooling, 42 days are needed to complete testing repeating 1,000 cycles. However, according to the present invention, around 5 minutes are enough for each of heating and cooling, and this may considerably reduce the development time, and simultaneously restrict the energy being required.

Furthermore, without actually using a large-scale facility such as the reflow furnace and the high-pressure pressing hot-press machine, similar thermal history can be reproduced by the heater.

### <Fourth Embodiment>

### (Device Chip)

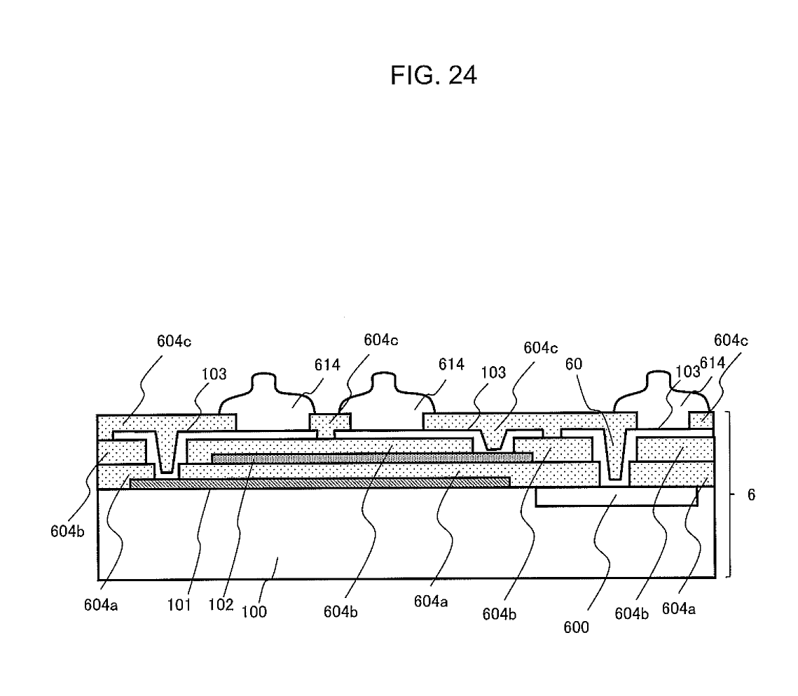

FIG. 24 is a cross sectional view showing a device chip 6 relating to the fourth embodiment of the present invention.

The device chip 6 is different from the semiconductor chip 1 in the point that the device chip is provided with a semiconductor device 600 and an aperture 60 for establishing connection thereof.

Specifically, the device chip 6 is configured by sequentially laminating the following; the semiconductor device 600 provided on one surface of the silicon substrate 100, the metal wiring film 101 serving as the resistance temperature detector, provided in such a manner as not coming into contact with the semiconductor device 600, a polyimide film 604a serving as an insulation layer, the metal wiring film 102 serving as the heater, a polyimide film 604b serving as the insulation layer, an electrode 103 electrically connecting with the semiconductor device 600, the metal wiring film 101, and the metal wiring film 102, and a polyimide film 604c serving as a protection layer. It is assumed here that Au bumps 614 are utilized for establishing connection with the substrate. In the configuration here, the semiconductor device 600 is not electrically connected with the metal wiring film 101. However, any one of the metal wiring film 101 and the metal wiring film 102 maybe connected with the semiconductor device 600.

Furthermore, the device chip 6 is not limited to the configuration above, and it may be modified in the same manner as the aforementioned modification examples 2 to 4.

More particularly, various temperature profiles similar to the examples above may be obtained, if an evaluation system is produced by mounting the device chip 6 on the substrate.

### (Repairing Method of the Device Chip)

When multiple device chips are mounted in high density, there is a possibility that poor connection occurs in a particular device chip. On this occasion, if only this particular device chip can be repaired, it is possible to enhance yield of a product.

Some repairing systems utilize hot air, a laser, or the like, but directivity of the hot air is limited, thus resulting in that peripheral chips are also heated simultaneously. Therefore, it is not adequate to the repair of the particular semiconductor chip only. On the other hand, it is difficult for the laser to heat a lot of bumps evenly, and in particular, if there is any shielding between the light source and the chip, repairing becomes extremely difficult.

The device chip 6 relating to the fourth embodiment of the present invention enables a specific semiconductor chip to be detached for repairing.

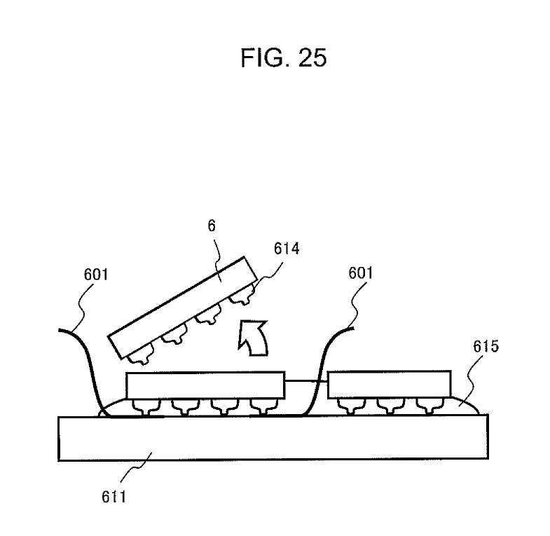

FIG. 25 illustrates repairing of the device chip 6 mounted on a substrate 611.

The device chip 6 of the present invention is adhered to and mounted on the substrate 611 by means of fixing materials, i.e. , Au bumps 614 and non-electro conductivity film 615. It is to be noted that the electrode 103 is electrically connected to the substrate wiring of the substrate 611, and each wiring is pulled out collectively as a wiring group 601. The wiring group 601 connects the metal wiring film 101 being the resistance temperature detector with an ammeter and a voltmeter, not illustrated, and also establishes connection between the metal wiring film 102 being the heater and an external power source, not illustrated.

Repairing of the device chip 6 as described above may be executed by heating the heater up to the temperature over a glass transition point of the non-electro conductivity film, while monitoring the temperature by the resistance temperature detector, and detaching only the device chip 6 from the substrate 611. Afterwards, the device chip 6 is repaired and mounted on the substrate 611 again, thereby achieving a selective repairing of the particular device chip without reducing connection reliability of other device chip. Consequently, this allows enhancement of yield.

It is to be noted that in the case where the device chip 6 is mounted on the substrate via a solder ball instead of Au bump 614, similar effect may be obtained by heating the solder ball up to a melting point thereof.

### <Fifth Embodiment>

### (Rechargeable Battery)

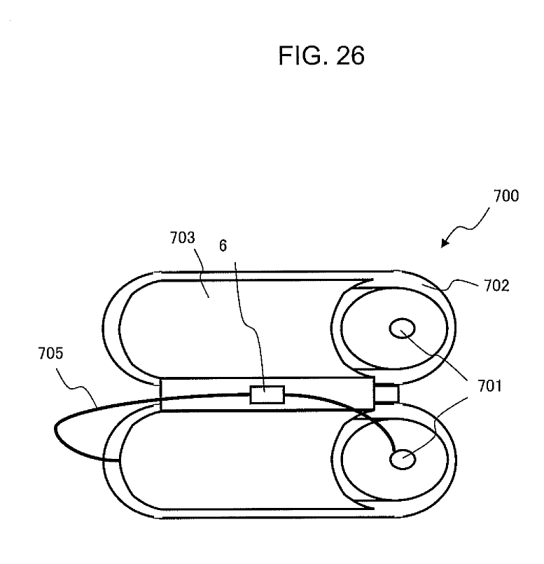

FIG. 26 is a schematic diagram of a rechargeable battery 700 incorporating the device chip 6, relating to the fifth embodiment of the present invention.

The rechargeable battery 700 incorporates electrodes 701, a package 702 being an enclosure, a metal plate 703, the device chip 6 bonded on the metal plate 703, and wiring 705 for connecting heater wiring of the device chip 6 and the rechargeable battery 700. It is to be noted that the metal wiring film 101 being the resistance temperature detector of the device chip 6 is assumed as connected to an ammeter and a voltmeter, not illustrated.

In the rechargeable battery 700 having such configuration as described above, the device chip 6 monitors ambient temperature of the rechargeable battery 700 according to the resistance temperature detector. If the ambient temperature becomes lower than a predetermined value, power is supplied to the heater of the device chip 6 using the rechargeable battery as an external power source, so as to avoid a situation that cell voltage of the rechargeable battery goes down. Accordingly, it is possible to prevent lowering of the cell voltage due to the depression of the ambient temperature.

It is to be noted that the embodiments of the invention in the preceding description are intended to be illustrative, rather than limiting, of the spirit and scope of the present invention. More specifically, those skilled in the art will readily appreciate that the invention embraces all alternatives, modifications, and variations.

1. An evaluation system for evaluating a semiconductor chip, comprising,
the semiconductor chip having on one surface of a semiconductor substrate, at least any of a first wiring film serving as a resistance temperature detector made up of multiple regions, and a second wiring film serving as a heater made up of one or more regions, and an electrode for electrically connecting the first wiring film and the second wiring film,
a mount substrate for mounting the semiconductor chip, and a thermally conductive material fixed on the mount substrate, on the other surface of the semiconductor substrate, wherein,
the first wiring film is electrically connected to an ammeter and a voltmeter, enabling measurement of temperature of each region, and
the second wiring film is electrically connected to a power source, enabling being heated of each region.

2. The evaluation system according to claim 1, wherein,
the first wiring film and the second wiring film are formed in an identical plane on the semiconductor substrate.

3. The evaluation system according to claim 1, wherein,
the first wiring film and the second wiring film are laminated, placing an insulation layer therebetween.

4. The evaluation system according to claim 1, wherein,
the first wiring film is platinum wiring film.

5. The evaluation system according to claim 1, wherein,
the second wiring film is nickel wiring film.

6. The evaluation system according to claim 1, wherein,
the second wiring film is further electrically connected to the ammeter and the voltmeter, thereby allowing the second wiring film to function as both the heater and the resistance temperature detector.

7. The evaluation system according to claim 1, further comprising,
a temperature measurement means for measuring temperature of the thermally conductive material.

8. The evaluation system according to claim 1, wherein,
the thermally conductive material is fixed on the mount substrate.

9. A semiconductor chip used for evaluation, comprising a semiconductor substrate, and further comprising on a plane of the semiconductor substrate,
an insulation layer,
multiple first wiring film serving as a resistance temperature detector, made up of multiple regions,
one or more second wiring film serving as a heater, made up of one or more regions,
a first electrode electrically connected to the first wiring film, and
a second electrode electrically connected to the second wiring film.

10. The semiconductor chip used for evaluation according to claim 9, wherein,
the first wiring film and the second wiring film are laminated placing the insulation layer therebetween.

11. The semiconductor chip used for evaluation according to claim 10, wherein,
the first wiring film is provided closer to the semiconductor substrate side than the second wiring film.

12. The semiconductor chip used for evaluation according to claim 10, wherein,
the second wiring film is provided closer to the semiconductor substrate side than the first wiring film.

13. The semiconductor chip used for evaluation according to claim 10, wherein,
the number of the regions of the first wiring film is larger than the number of the regions of the second wiring film.

14. The semiconductor chip used for evaluation according to claim 10, wherein,
the region for placing one second wiring film is larger than the region for placing one first wiring film.

15. The semiconductor chip used for evaluation according to claim 9, wherein,
the first wiring film and the second wiring film are arranged in an identical plane.

16. The semiconductor chip used for evaluation according to claim 9, wherein,
the first wiring film is platinum wiring film.

17. The semiconductor chip used for evaluation according to claim 9, wherein,
the second wiring film is nickel wiring film.

18. The semiconductor chip used for evaluation according to claim 9, wherein,
the first wiring film has the first electrodes used in a pair for each region, and
the second wiring film has the second electrodes used in a pair for each region.

19. The semiconductor chip used for evaluation according to claim 18, wherein,
four first electrodes are provided in one region of the first wiring film.

20. A repairing method for repairing the evaluation system according to claim 1, executing,
a step for heating either of the first wiring film and the second wiring film to melt a fixing material on the mount substrate,
a step for removing a device chip from the mount substrate,
a step for repairing the device chip being removed, and
a step for mounting the device chip on the mount substrate again.
